(19) United States
(12) Patent Application Publication
(10) Pub. No.: US 2017/0254938 A1
(43) Pub. Date: Sep. 7, 2017

(54) POLARIZER, POLARIZING PLATE, AND IMAGE DISPLAY DEVICE

(71) Applicant: FUJIFILM Corporation, Tokyo (JP)

(72) Inventors: Takahiro OHNO, Kanagawa (JP); Ryo SATAKE, Kanagawa (JP); Michio ARAI, Kanagawa (JP); Yuko TERAO, Kanagawa (JP)

(73) Assignee: FUJIFILM Corporation, Tokyo (JP)

(21) Appl. No.: 15/598,869

(22) Filed: May 18, 2017

Related U.S. Application Data
(63) Continuation of application No. PCT/JP2015/086327, filed on Dec. 25, 2015.

(30) Foreign Application Priority Data
Dec. 26, 2014 (JP) 2014-265395

(51) Int. Cl. G02B 5/30; C08K 3/16; C08J 5/18; H01L 51/00

(52) U.S. Cl. CPC G02B 5/30; H01L 51/004; C08K 3/16; C08J 5/18; G02F 1/133528

(57) ABSTRACT

The present invention addresses the problem of providing a polarizer maintaining an excellent degree of polarization and having high transmittance and excellent durability, and a polarizing plate and an image display device using the same. This polarizer has a polyvinyl alcohol-based resin and iodine included in the polyvinyl alcohol-based resin, in which the thickness of the polarizer is 2 to 20 μm, the degree of orientation of the polyvinyl alcohol-based resin is 0.11 or more and 0.16 or less, the iodine content is more than 0.50 g/m² and 1.0 g/m² or less, and the product of the degree of orientation of the polyvinyl alcohol-based resin and the iodine content is 0.08 g/m² or more and 0.11 g/m² or less.

### CROSS-REFERENCE TO RELATED APPLICATIONS

This application is a Continuation of PCT International Application No. PCT/JP2015/086327 filed on Dec. 25, 2015, which claims priority under 35 U.S.C. §119(a) to Japanese Patent Application No. 2014-265395 filed on Dec. 26, 2014. The above application is hereby expressly incorporated by reference, in its entirety, into the present application.

### BACKGROUND OF THE INVENTION

1. Field of the Invention

The present invention relates to a polarizer, a polarizing plate, and an image display device.

2. Description of the Related Art

As a polarizer used for image display devices such as a liquid crystal display device, an electroluminescent (EL) display device, a plasma display (PD), and a field emission display (FED), a dyed polyvinyl alcohol-based film has been used for the reason that the film has both a high transmittance and a high degree of polarization.

This polarizer is produced by, for example, carrying out each treatment of swelling, dying, cross-linking, stretching, and the like on a polyvinyl alcohol-based resin in a bath and then carrying out drying after a washing treatment (for example, refer to JP2001-141926A).

In recent years, performance enhancement and thickness reduction of an image display device have advanced and there has been a demand for thickness reduction of a polarizer with this advance.

For example, JP2009-098653A discloses a “polarizing plate containing a stretched laminate which is obtained by stretching a laminate formed by laminating a base layer and a hydrophilic polymer layer in winch at least a dichroic material is adsorbed into the hydrophilic polymer layer” as a polarizing plate having a polarizer in which the occurrence of curling is suppressed even in the case in which the thickness of the polarizer is reduced ([Claim 1] and [0007]).

### SUMMARY OF THE INVENTION

The present inventors have found that although conventionally known polarizers described in JP2001-141926A, JP2009-098653A, and the like exhibits high and satisfactory degree of polarization, the transmittance has to be improved, and the moisture permeability increases according to thickness reduction to cause an increase in amount of moisture infiltration into the polarizer, thereby deteriorating durability, particularly, deteriorating polarization performance after the lapse of time under a high temperature and high humidity condition.

Here, an object of the present invention is to provide a polarizer maintaining an excellent degree of polarization and having a high transmittance and excellent durability, and a polarizing plate and an image display device using the same.

As a result of conducting intensive investigations to achieve the above object, the present inventors have found that a polarizer in which the degree of orientation of a polyvinyl alcohol-based resin, the content of iodine as a dichroic material, and the product thereof are in specific ranges has a high transmittance and excellent durability while maintaining a high degree of polarization, and thus have completed the present invention.

That is, it has been found that the above object can be achieved by adopting the following configurations.
[1] A polarizer comprising: a polyvinyl alcohol-based resin; and iodine contained in the polyvinyl alcohol-based resin,
   in which a thickness of the polarizer is 2 to 20 μm,
   a degree of orientation of the polyvinyl alcohol-based resin is 0.11 or more and 0.16 or less,
   a content of the iodine is more than 0.50 g/m² and 1.0 g/m² or less, and
   a product of the degree of orientation of the polyvinyl alcohol-based resin and the iodine content is 0.08 g/m² or more and 0.11 g/m² or less.
[2] The polarizer according to [1], in which the product of the degree of orientation of the polyvinyl alcohol-based resin and the iodine content is 0.082 g/m² or more and 0.110 g/m² or less.
[3] The polarizer according to [1] or [2], in which an absorbance of the polarizer at a wavelength of 250 to 400 nm is 15 or more and 30 or less.
[4] The polarizer according to [3], in which a product of the degree of orientation of the polyvinyl alcohol-based resin and the absorbance of the polarizer at a wavelength of 250 to 400 nm is 1.70 or more and 4.0 or less.
[5] A polarizing plate comprising: the polarizer according to any one of [1] to [4].
[6] An image display device comprising: the polarizer according to any one of [1] to [4]; or the polarizing plate according to [5].

According to the present invention, it is possible to provide a polarizer maintaining an excellent degree of polarization and having a high transmittance and excellent durability, and a polarizing plate and an image display device using the same.

### DESCRIPTION OF THE PREFERRED EMBODIMENTS

Hereinafter, the present invention will be described in detail.

The description of the constitutional requirements described below is made on the basis of representative embodiments of the present invention, but it should not be construed that the present invention is limited to those embodiments.

In this specification, numerical value ranges expressed by the term “to” mean that the numerical values described before and after “to” are included as a lower limit and an upper limit, respectively.

### Polarizer

A polarizer of the present invention is a polarizer having a polyvinyl alcohol-based resin, and iodine contained in the polyvinyl alcohol-based resin, in which the thickness of the polarizer is 2 to 20 μm, the degree of orientation of the polyvinyl alcohol-based resin is 0.11 or more and 0.16 or less, the iodine content is more than 0.50 g/m² and 1.0 g/m² or less, and the product of the degree of orientation of the polyvinyl alcohol-based resin and the iodine content is 0.08 g/m² or more and 0.11 g/m² or less.

Here, the degree of polarization, transmittance, and durability indicating, the performance of the polarizer of the present invention are performance respectively measured by the following methods.

<Degree of Polarization>

The degree of polarization is obtained by applying a transmittance (parallel transmittance: Tp) in the case of superimposing two polarizers while making the transmission axes of the polarizers in conformity with each other, and a transmittance (crossed transmittance: Tc) in the case of superimposing two polarizers while making the transmission axes of the polarizers orthogonal to each other to the following equation.

Degree of polarization (%)={(Tp−Tc)/(Tp+Tc)}^{1/2}×100

Each transmittance is measured at a wavelength of 550 nm using an automatic polarizing film measuring device VAP-7070 manufactured by JASCO Corporation and is a Y value obtained by subjecting the measurement to visibility correction by a 2 degree field of view (C light source according to JIS Z8701 while setting complete polarization obtained through a Gran Teller prism polarizer to 100%.

<Transmittance>

The transmittance refers to a unit transmittance (Ts) measured at a wavelength of 550 nm using an automatic polarizing film measuring device VAP-7070 manufactured by JASCO Corporation and is a Y value obtained by subjecting the measurement to visibility correction by a 2 degree field of view (C light source) according to JIS Z8701.

<Durability>

The durability is evaluated based on an amount of change of the perpendicular transmittance before and after a durability test.

Here, the perpendicular transmittance in the durability evaluation is measured 10 times in a range of 380 nm to 780 nm using an automatic polarizing film measuring device VAP-7070 manufactured by JASCO Corporation and the average value of the measured values at 410 nm is adopted.

In addition, the durability is obtained by measuring the perpendicular transmittance before and after a test of leaving the polarizing plate for 500 hours under environment of 60° C. and a relative humidity of 95%, and before and after a test of leaving the polarizing plate for 500 hours under environment of 80° C. and a relative humidity of 0% to 20%, and calculating an amount of change of the perpendicular transmittance.

In the polarizer of the present invention, the degree of orientation of the polyvinyl alcohol (hereinafter, also abbreviated as “PVA”)-based resin is 0.11 or more and 0.16 or less, the iodine content is more than 0.50 g/m² or more and 1.0 g/m² or less, and the product of the degree of orientation of the polyvinyl alcohol-based resin and the iodine content is 0.08 g/m² or more and 0.11 g/m² or less. Even when the thickness is 2 to 20 μm, the polarizer maintains an excellent degree of polarization and has a high transmittance and satisfactory durability.

Although the details are not clear, the reason for obtaining an excellent degree of polarization, a high transmittance, and satisfactory durability as described above is assumed as follows.

First, in the polarizer using iodine as a dichroic material, it is considered that the iodine is ionized in the polarizer and is present in a state of polyiodide ions of I− and higher order than I− (in the following Formula (I), polyiodine A and polyiodine B) as shown in the equilibrium reaction represented by the following Formula (I).

Of these, it is known that polyiodide ions of higher order than I− affect polarization performance and these polyiodide ions are complexed with PVA to form complexes (in the Formula (I), complex A and complex B) and are oriented along the oriented PVA so as to exhibit polarization performance.

It is known that the complex of the polyiodide ions of higher order than I− and PVA act on the absorption in the vicinity of a wavelength of 480 nm and in the vicinity of a wavelength of 610 nm and in the present invention, among the complexes of polyiodide ions and PVA, a complex which acts on the absorption in the vicinity of a wavelength of 480 nm is defined as a complex A, and a complex which acts on the absorption in the vicinity of a wavelength of 610 nm is defined as a complex B.

In addition, it is known that in a state in which the polyiodide ions of higher order than I− are not complexed with PVA, the absorption in a wavelength of 400 to 800 nm hardly occurs.

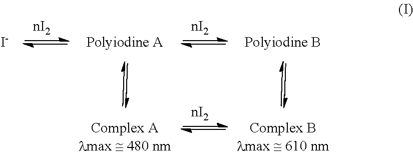

In the present invention, it is considered that since the iodine content is as high as more than 0.50 g/m² and 1.0 g/m² or less, the equilibrium reaction in which the complex A and the complex B return to polyiodine A and the polyiodine B hardly occurs and thus the durability becomes satisfactory while maintaining a high degree of polarization.

In addition, it is considered that since PVA can be further stretched by suppressing the crystallization of PVA when PVA is stretched by setting the iodine content to be in the above range, as a result, the degree of orientation of PVA can be set to 0.11 or more and 0.16 or less so that the transmittance becomes high.

Further, it is considered that since the product of the degree of orientation of PVA and the iodine content is 0.08 g/m² or more and 0.11 g/m² or less, even when the iodine content is high, the degree of orientation of PVA becomes high and as a result, the degree of orientation of the polyiodide ions also becomes high so that a high degree of polarization and a high transmittance can be attained.

### Polyvinyl Alcohol-Based Resin

The polyvinyl alcohol-based resin of the polarizer of the present invention is not particularly limited as long as the degree of orientation is 0.11 or more and 0.16 or less.

Here, the degree of orientation refers to a value calculated using the following measurement device under the following conditions by a wide-angle X-ray diffraction method (hereinafter, abbreviated as “WAXS”).

<Measurement Device>

RAPID R-AXIS (manufactured by Rigaku Corporation)

<Measurement Conditions>
X-ray Source: Cukα-ray
Collimator: 0.8 mmφ
Measurement: transmissive two-dimensional 2θ
X-ray Irradiation Time: 3 minutes

Here, as a parameter indicating the orientation of PVA, the degree of orientation P calculated by X-ray diffraction measurement is used. The degree of orientation P of PVA is defined by the following equation (A) from the detected X-ray pattern. The upper limit of the degree of orientation P is 1.0.

P=<(3 cos β)̂2−1>/2 Equation (A)

Herein, <cosβ>̂2=∫(0,π)(cosβ)̂2 I(β)sinβdβ/∫(0,π)I(β)sinβdβ. In the above equation, β is an angle formed by the incident surface of incident X-rays and one direction in PVA film plane, and I is an integral value of the diffraction intensity at 2θ=18.5° to 21.5° in the X-ray diffraction chart measured at the angleβ.

As the material for the polyvinyl alcohol-based resin, for example, polyvinyl alcohol or derivatives thereof may be used.

Specific examples of the derivatives of polyvinyl alcohol include polyvinyl formal; polyvinyl acetal; and modified polyvinyl alcohol, polyvinyl formal, polyvinyl acetal or the like with olefins such as ethylene and propylene, unsaturated carbonic acids such as acrylic acid, methacrylic acid, and crotonic acid, or the like.

In addition, the degree of polymerization of the polyvinyl alcohol is preferably about 100 to 10,000 and more preferably 1,000 to 10,000. The degree of saponification of the polyvinyl alcohol generally used is about 80% to 100% by mole.

Additives such as a plasticizer and a surfactant can be added to the polyvinyl alcohol-based resin.

Examples of the plasticizer include polyols and their condensates and the like, and specifically, glycerol, diglycerol, triglycerol, ethylene glycol, propylene glycol, polyethylene glycol, and the like may be used.

The amount of the plasticizer or the like used is not particularly limited, but the amount used is preferably 20% by mass or less in the polyvinyl alcohol-based resin.

### Iodine

Iodine is used as a dichronic material contained in the polyvinyl alcohol-based resin.

The iodine content is more than 0.50 g/m² and 1.0 g/m² or less and is preferably 0.80 to 1.0 g/m² and more preferably 0.85 to 1.0 g/m².

Here, the iodine content is measured using a combustion halogen analyzer (AQF-100, manufactured by Mitsubishi Chemical Analytech Co., Ltd.) under the following conditions.

Specifically, the iodine content refers to an amount (g/m²) of iodine or dye absorbed in an absorption liquid (hydrogen peroxide solution) and the iodine or dye is generated by punching the polarizer to form a sample of 3 mmφ, and burning the sample on a quartz board.

<Combustion Conditions>
Combustion temperature: Inlet 900° C., Outlet 1,000° C.
ABC Parameter: 1st pos. 130 Time 150 s, 2nd pos. 140 Time 120 s, 3rd nos. 150 Time 120 s, End Time 240 s, Cool 60 s

<Ion Chromatography Detector Conditions>
Column: AS12A
Fluent: 2.7 mmol/L, Na₂CO₃+0.3 mmol/L NaHCO₃
Flow Rate: 1.5 ml/min
Column Temperature: 35° C.

In the present invention, for the reason that the durability of the polarizer is further improved, the absorbance of the polarizer at a wavelength of 250 to 400 nm is preferably 15 or more and 30 or less.

Here, the “absorbance of the polarizer at a wavelength of 250 to 400 nm” refers to a value obtained from the area of a fitting curve obtained by measuring the absorption spectrum (measurement wavelength: 250 to 400 nm) of the polarizer using an ultraviolet visible near infrared spectrophotometer (V-7200, manufactured by JASCO Corporation) and the peak at 295 nm in the obtained spectrum with the Gaussian curve.

In addition, it is considered that the reason that the durability of the polarizer is further improved by setting the absorbance of the polarizer at a wavelength of 250 to 400 nm to 15 or more and 30 or less is that the equilibrium reaction in which the complex A which acts on the absorption in the vicinity of a wavelength of 480 nm returns to the polyiodine A in the equilibrium reaction represented by the above Formula (I) is suppressed.

In the present invention, the product of the above-described degree of orientation of the polyvinyl alcohol-based resin and the above-described iodine content is 0.08 g/m² or more and 0.11 g/mm² or less, but for the reason that the durability of the polarizer is further improved, the product is preferably 0.082 g/m² or more and 0.110 g/m² or less and more preferably 0.085 g/m² or more and 0.105 g/m² or less.

For the same reason, the product of the above-described degree of orientation of the polyvinyl alcohol-based resin and the absorbance of the polarizer at a wavelength of 250 to 400 nm is preferably 1.70 or more and 4.0 or less and more preferably 2.12 to 3.5.

<Thickness>

The thickness of the polarizer of the present invention is 2 to 20 μm and is preferably 15 μm or less and more preferably 10 μm or less.

### Method of Producing Polarizer

The method of producing the polarizer of the present invention is not particularly limited and for example, the polarizer can be produced by subjecting a raw film made of a polyvinyl alcohol-based resin (hereinafter, abbreviated as a “PVA raw film” before iodine is adsorbed into a polyvinyl alcohol-based resin film) to a dyeing treatment of adsorbing iodine.

In addition, for the reason that the above-described iodine content is easily controlled to be more than 0.50 g/m² and 1.0 g/m² or less, it is preferable that the PVA raw film before the above-described dyeing treatment is carried out is subjected to a swelling treatment of immersing the film in water or the like.

Further, it is preferable that a stretching treatment is carried out before, during, or after the above-described dyeing treatment, and for the reason that the orientation of iodine to be adsorbed into the PVA raw film becomes satisfactory, it is more preferable that a stretching treatment is carried out before the dyeing treatment. It is still more preferable that a stretching treatment is carried out before and after the dyeing treatment.

<Swelling Treatment>

For a swelling bath for carrying out a swelling treatment, water or warm water is mainly used.

The immersion time of PVA raw film in the swelling bath at the swelling treatment is preferably 30 seconds or longer and 300 seconds or shorter and more preferably 45 seconds or longer and 180 seconds or shorter.

In addition, for the swelling treatment, other than the immersion of the film in the swelling bath as described above, a method of carrying out the swelling treatment while applying and spraying water or warm water to the PVA raw film can be adopted.

Further, the swelling treatment can be carried out during the stretching treatment to be described later. In the case of carrying out stretching during the swelling treatment, the stretching ratio with respect to the original length of the PVA raw film is preferably 1.1 times or higher and more preferably 1.2 times or higher.

<Stretching Treatment>

The stretching treatment is preferably carried out by uniaxial stretching.

For the uniaxial stretching, any of vertical stretching which is carried out on the PVA raw film to in a longitudinal direction and lateral stretching which is carried out on the PVA raw film in a width direction can be adopted. In the present invention, the uniaxial stretching is preferably carried out by lateral stretching. In the lateral stretching, the film can be shrunk in the longitudinal direction while stretching in the width direction. As the lateral stretching method, for example, a fixed-end uniaxial stretching method of fixing one end through a tenter, a free-end uniaxial stretching method of not fixing one end, or the like may be used. As the vertical stretching method, a roll-to-roll stretching method, a pressure stretching method, a stretching method using a tenter, or the like may be used. The stretching treatment can be carried out in multi-stages. In addition, the stretching treatment can be carried out by performing biaxial stretching, oblique stretching, and the like.

In addition, for the stretching treatment, any of a wet stretching method and a dry stretching method can be adopted. In the present invention, it is preferable to use a dry stretching method from the viewpoint of setting a wide temperature range when the PVA raw film is stretched. In the drying stretching method, typically, the PVA raw film is preferably subjected to a stretching treatment in a state in which the raw film is heated to about 50° C. to 200° C. and the heating temperature is more preferably 80° C. to 180° C. and still more preferably 100° C. to 160° C.

The stretching treatment is carried out in a range of a total stretching ratio of preferably 1.5 to 17 times the original length of the PVA raw film, more preferably 1.5 to 10 times the original length of the PVA raw film, and still more preferably 1.5 to 8 times the original length of the PVA raw film. The total stretching ratio refers to an accumulated stretching ratio including, in the case of carrying out stretching in steps other than the stretching treatment step, stretching in these steps. The total stretching ratio is appropriately determined considering the stretching ratios in other steps.

<Dyeing Treatment>

The dyeing treatment is carried out by adsorbing iodine into the PVA raw film.

The dyeing treatment is preferably carried out by, for example, immersing the PVA raw film in a solution containing iodine (dyeing solution).

As the dyeing solution, a solution obtained by dissolving iodine in a solvent can be used.

As the solvent, water is generally used, but an organic solvent having compatibility with water may be further added. The concentration of iodine is preferably in a range of 0.01% to 10% by mass, more preferably in a range of 0.02% to 7% by mass, and still more preferably in a range of 0.025% to 5% by mass.

In addition, from the viewpoint of further enhancing the dyeing efficiency, it is preferably to further add an iodide the solution.

Examples of the iodide include potassium iodide, lithium iodide, sodium iodide, zinc iodide, aluminum iodide, lead iodide, copper iodide, barium iodide, calcium iodide, tin iodide, and titanium iodide. The addition ratio of these iodides is preferably 0.01% to 10% by mass and more preferably 0.1% to 5% by mass with respect to the dyeing solution. Among these, it is preferable to add a potassium iodide to the solution and the ratio between iodine and potassium iodide (weight ratio) is preferably in a range of 1:5 to 1:100, more preferably in a range of 1:6 to 1:80, and particularly preferably in a range of 1:7 to 1:70.

The immersion time of the PVA raw film in the dyeing solution is not particularly limited and typically, the immersion time is preferably in a range of 15 seconds to 5 minutes and more preferably in a range of 1 minute to 3 minutes. In addition, the temperature of the dyeing solution is preferably in a range of 10° C. to 60° C. and more preferably in a range of 20° C. to 40° C.

### Polarizing Plate

The polarizing plate of the present invention is a polarizing plate having the above-described polarizer of the present invention and may further have, for example, an outer protective film provided on the visible side of the polarizer, a hard coat layer, and the like in addition to the polarizer.

Hereinafter, each arbitrary layer constituting the polarizing plate of the present invention other than the polarizer will be described in detail.

### Outer Protective Film

An arbitrary outer protective film that the polarizing plate of the present invention may have is not particularly limited and specific examples thereof include thermoplastic resin films such as a cellulose acylate-based film, a (meth)acrylic resin film, a cycloolefin-based resin film, a polyester-based resin film, a polycarbonate-based resin film, and a polyolefin-based resin film.

It should be noted that (meth)acrylic resin is a concept containing both of methacrylic resin and acrylic resin and also includes an acrylate/methacrylate derivative and in particular an acrylate ester/methacrylate ester (co)polymer. In addition to methacrylic resin and acrylic resin, the (meth)acrylic resin also includes a (meth)acrylic polymer having a ring structure in the main chain, examples thereof including a lactone ring-containing polymer, a succinic anhydride ring-containing maleic anhydride polymer, a glutaric anhydride ring-containing polymer and a glutarimide ring-containing polymer.

Among these, a cellulose acylate film and a (meth)acrylic resin film are preferable in terms of workability and optical performance.

Various known cellulose acylate-based films may be suitably used as polymer films and specific examples of the cellulose acylate-based films that may be used include those described in JP2012-076051A.

In addition, various known (meth)acrylic resin films may be used and specific examples of the (meth)acrylic resin films that may be suitably adopted include acrylic films described in paragraphs [0032] to [0063] of JP2010-079175A and lactone ring-containing polymers described in paragraphs [0017] to [0107] of JP2009-98605A.

<Thickness>

The thickness of the outer protective film is preferably 5 μm to 30 μm and more preferably 10 μm to 25 μm from the viewpoint of thickness reduction of the polarizing plate.

### Hard Coat Layer

The polarizing plate of the present invention preferably has an inner hard coat layer on the side of the polarizer opposite to the side on which the outer protective film is provided (on the side on which a liquid crystal cell or an organic EL display panel is to be provided in an image display device to be described later).

Similarly, the polarizing plate of the present invention preferably has an outer hard coat layer on the side of the outer protective film opposite to the side on which the polarizer is provided (on the visible side in an image display device to be described later).

The hard coat layer is preferably formed by a crosslinking reaction or a polymerization reaction of an ionizing radiation-curable compound.

For example, the hard coat layer can be formed by applying a coating composition including an ionizing radiation-curable polyfunctional monomer or polyfunctional oligomer onto the protective layer to be described later to crosslink or polymerize the polyfunctional monomer or polyfunctional oligomer.

The functional group of the ionizing radiation-curable polyfunctional monomer or polyfunctional oligomer is preferably photopolymerizable, electron beam polymerizable or radiation polymerizable, and a photopolymerizable functional group is particularly preferable.

Examples of the photopolymerizable functional group include unsaturated polymerizable functional groups such as (meth)acryloyl group, vinyl group, styryl group and allyl group, and among these, a (meth)acryloyl group is preferable. Here, the (meth) acryloyl group is an expression representing an acryloyl group or a methacryloyl group.

In order to impart internal scattering properties, the hard coat layer may contain matte particles having an average particle diameter of 1.0 μm to 10.0 μm and preferably 1.5 μm to 7.0 μm, as exemplified by inorganic compound particles or resin particles.

As the hard coat layer, for example, those described in paragraphs [0190] to [0196] of JP2009-98658A can be used.

<Thickness>

The inner hard coat layer and the outer hard coat layer each independently have a thickness of preferably 7 μm or less and more preferably 1 μm to 5 μm.

### Pressure Sensitive Adhesive Layer and Adhesive Layer

The polarizing plate of the present invention may have a pressure sensitive adhesive layer or an adhesive layer in advance in consideration of lamination with a liquid crystal cell or an organic EL display panel in an image display device to be described later.

The pressure sensitive adhesive and the adhesive that can be used in the present invention are not particularly limited and usually used pressure sensitive adhesives (for example, an acrylic pressure sensitive adhesive) and adhesives (for example, a polyvinyl alcohol adhesive) can be used.

In addition, pressure-sensitive adhesives described in paragraphs [0100] to [0115] of JP2011-037140A and paragraphs [0155] to [0171] of JP2009-292870A can be used for the pressure-sensitive adhesive and the adhesive that can be used in the present invention.

### Image Display Device

The image display device of the present invention is an image display device having the above-described polarizer of the present invention or the polarizing plate of the present invention.

Suitable examples of the image display device include a liquid crystal display device and an organic EL display device to be described later.

### Liquid Crystal Display Device

A liquid crystal display device which is an example of the image display device of the present invention is, for example, a liquid crystal display device having a liquid crystal cell and a pair of polarizing plates disposed so as to sandwich the liquid crystal cell therebetween, and an embodiment in which at least one of the polarizing plates in the pair is constituted by the above-described polarizing plate of the invention is suitably used.

In the present invention, among the polarizing plates provided on both sides of the liquid crystal cell, the polarizing plate of the present invention is preferably used as the polarizing plate on the visible side and the polarizing plates of the present invention are more preferably used as the polarizing plates on the visible side and the backlight side.

<Liquid Crystal Cell>

The liquid crystal cell for use in the image display device (liquid crystal display device) of the present invention is preferably of a vertical orientation (VA) mode, an optically compensated bend (OCB) mode, an in-plane-switching (IPS) mode or a twisted nematic (TN) mode but the cell mode is not limited thereto.

In a TN mode liquid crystal cell, rod-like liquid crystal molecules are oriented substantially horizontally when no voltage is applied and are further oriented in a twisted manner in a range of 60° to 120°. The TN mode liquid crystal cell is most often used in a color TFT liquid crystal display device and is mentioned in a large number of literatures.

In a VA mode liquid crystal cell, rod-like liquid crystal molecules are oriented substantially vertically when no voltage is applied. Examples of the VA mode liquid crystal cells include (1) a narrowly defined VA mode liquid crystal cell (described in JP1990-176625A (JP-H02-176625A)) in which rod-like liquid crystal molecules are oriented substantially vertically when no voltage is applied and are oriented substantially horizontally when a voltage is applied, (2) a multi-domain VA mode (MVA mode) liquid crystal cell for enlarging the viewing angle (SID97, Digest of Tech. Papers (Proceedings) 28 (1997) 845), (3) a liquid crystal cell in a mode (n-ASM mode) in which rod-like liquid Crystal molecules are oriented substantially vertically when no voltage is applied and are oriented in twisted multi-domain orientation when a voltage is applied (Proceedings of Japanese Liquid Crystal Conference, 58-59 (1998)), and (4) a SURVIVAL mode liquid crystal cell (presented in LCD International 98). The liquid crystal cell may be of any of patterned vertical orientation (PVA) type, optical orientation type and polymer-sustained orientation (PSA) type. These modes are described in detail in JP2006-215326A and JP2008-538819A.

In an IPS mode liquid crystal cell, rod-like liquid crystal molecules are oriented substantially horizontally with respect to a substrate and application of an electric field parallel to the substrate surface causes the liquid crystal molecules to respond planarly. The IPS mode displays black when no electric field is applied and a pair of upper and lower polarizing plates have absorption axes which are orthogonal to each other. A method of improving the viewing angle by reducing light leakage during black display in an oblique direction using an optical compensation sheet is described in JP1998-54982A (JP-H10-54982A), JP1999-202323A (JP-H11-202323A), JP1997-292522A (JP-H09-292522A), JP1999-133408A (JP-H11-133408A), JP1999-305217A (JP-H11-305217A), JP1998-307291A (JP-H10-307291A), and the like.

### Organic EL Display Device

As the organic EL display device which is an example of the image display device of the present invention, for example, an embodiment which includes, from the visible side, the polarizing plate of the present invention, a plate having a λ/4 function (hereinafter referred to also as “λ/4 plate”) and an organic EL display panel in this order is suitable.

The “plate having a λ/4 function” as used herein refers to a plate having a function of converting linearly polarized light at a specific wavelength into circularly polarized light (or circularly polarized light into linearly polarized light). Specific examples of an embodiment in which the λ/4 plate is of a single layer structure include a stretched polymer film, and a phase difference film in which an optically anisotropic layer having a λ/4 function is provided on a support. A specific example of an embodiment in which the λ/4 plate is of a multilayer structure includes a broadband λ/4 plate in which the λ/4 plate and a λ/2 plate are laminated on each other.

The organic EL display panel is a display panel configured using an organic EL device in which an organic light emitting layer (organic electroluminescent layer) is sandwiched between electrodes (between a cathode and an anode).

The configuration of the organic EL display panel is not particularly limited but any known configuration is adopted.

### EXAMPLES

The present invention will be described below in further detail based on examples. The materials, amounts used, ratios, treatments and treatment procedures shown in the examples below can be modified as appropriate in the range of not departing from the spirit of the present invention, Therefore, the scope of the present invention should not be construed as being limited to the following examples.

<Preparation of PVA Raw Film>

200 kg of water at 18° C. was poured into 500 L tank and while stirring, 42 kg of a polyvinyl alcohol-based resin (weight-average molecular weight: 165,000, degree of saponification: 99.8% by mole) was added thereto, followed by stirring for 15 minutes. Thus, slurry was prepared.

The prepared slurry was dehydrated, thereby obtaining a polyvinyl alcohol-based resin wet cake having a water content ratio of 40%.

70 kg (resin content: 42 kg) of the obtained polyvinyl alcohol-based resin wet cake was put into a dissolving bath, and 4.2 kg of glycerol, as a plasticizer, and 10 kg of water were added thereto, water vapor was blown in from the bath bottom.

The components began to be stirred (at a rotation speed: 5 rpm) when the temperature of the resin in the dissolving bath (hereinafter, referred to as “inner resin temperature”) reached 50° C., and the inside of the system was pressurized when the inner resin temperature reached 100° C., and the blowing-in of water vapor was stopped when the inside resin temperature was further increased to 150° C. The amount of water vapor blown in was 75 kg.

Next, the components were stirred (rotation speed: 20 rpm) for 30 minutes so as to be homogeneously dissolved, and then an aqueous polyvinyl alcohol-based resin solution having a polyvinyl alcohol-based resin concentration of 23% by mass with respect to water was obtained by adjusting the concentration.

Next, the obtained aqueous polyvinyl alcohol-based resin solution (solution temperature: 147° C.) was supplied to a twin screw extruder from a supply gear pump 1, was defoamed, and then was discharged from a discharge gear pump 2.

The discharged aqueous polyvinyl alcohol-based resin solution was flow-cast on a cast drum using a T-shaped slit die (straight manifold die) so as to form a film, thereby obtaining a polyvinyl alcohol film. Thus, PVA raw films having the thickness shown in Table 1 below were obtained by changing the flow rate of the gear pump.

### Example 101

The above-prepared PVA raw film (thickness: 43 μm) was uniaxially stretched 1.30 times while being subjected to immersion (swelling treatment) in warm water at 40° C. for 2 minutes.

Next, the stretched film was immersed in an aqueous solution containing 0.30 g/L of iodine (manufactured by JUNSEI CHEMICAL CO., LTD.) and 1.2 g/L of potassium iodide (manufactured by JUNSEI CHEMICAL CO., LTD.) (solution temperature: 30° C.) for 2 minutes to carry out a dyeing treatment using iodine and an iodide.

A boric acid (manufactured by Societa Chimica Larderello s.p.a) treatment was carried out for 5 minutes in an aqueous solution (temperature: 50° C.) containing 30.0 g/L of boric acid while the film which had been subjected to the dyeing treatment was uniaxially stretched 10.0 times to prepare a film.

A polarizer was obtained by drying the prepared film for 9 minutes at 70° C.

### Examples 102 to 111 and Comparative Examples 101 to 105

Polarizers were obtained in the same manner as in Example 101 except that the thickness of the PVA raw film used, the water temperature in the swelling treatment, the concentration of iodine, the concentration of potassium iodide, and the stretching ratio were changed as shown in Table 1 below.

Here, each polarizer was repeatedly prepared 10 times under the same conditions and the breakage state at the time of stretching in the uniaxial stretching after the dyeing treatment was evaluated based on the following criteria. The results are shown in Table 1 below. Comparative Example 104 is an example in which a thin polarizer was prepared under the conditions shown in examples of JP2001-141926A, but as shown in Table 1 below, it was confirmed that three polarizers were broken at the time of stretching among 10 polarizers.
A: None of the prepared ten polarizers were broken.
B: One or two polarizers were broken among the ten prepared polarizers.
C: Three or more polarizers were broken among the ten prepared polarizers.

TABLE 1

| | | | Swelling treatment | | | | | | | |
|---|---|---|---|---|---|---|---|---|---|---|
| | | | and stretching | | | | | | | Breakage |
| | | PVA raw | treatment (before | | Dyeing treatment and | | | Stretching treatment | | evaluative |
| | | film | dyeing treatment) | | stretching treatment | | | (after dyeing treatment) | | at the |
| | | Thickness | Water | Stretching | Stretching | Iodine | Potassium | Water | Stretching | time of |
| | | [μm] | temperature | ratio | ratio | [%] | iodide [%] | temperature | ratio | stretching |
| Example | 101 | 43 | 40° C. | 1.3 times | 1.5 times | 0.30 | 1.2 | 50° C. | 10 times | A |
| Example | 102 | 35 | 40° C. | 1.3 times | 1.5 times | 0.35 | 1.2 | 50° C. | 10 times | A |
| Example | 103 | 28 | 40° C. | 1.3 times | 1.5 times | 0.40 | 1.2 | 50° C. | 10 times | A |
| Example | 104 | 23 | 40° C. | 1.3 times | 1.5 times | 0.45 | 1.2 | 50° C. | 10 times | A |
| Example | 105 | 19 | 40° C. | 1.3 times | 1.5 times | 0.50 | 1.2 | 50° C. | 10 times | A |
| Example | 106 | 40 | 40° C. | 1.3 times | 1.5 times | 0.20 | 1.2 | 50° C. | 10 times | A |
| Example | 107 | 35 | 40° C. | 1.3 times | 1.5 times | 0.20 | 1.2 | 50° C. | 8.5 times | A |
| Example | 108 | 43 | 40° C. | 1.3 times | 1.5 times | 0.15 | 1.2 | 50° C. | 10 times | A |
| Example | 109 | 53 | 40° C. | 1.3 times | 1.5 limes | 0.20 | 1.2 | 50° C. | 12 times | B |
| Example | 110 | 48 | 40° C. | 1.3 times | 1.5 times | 0.20 | 0.6 | 50° C. | 10 times | A |
| Example | 111 | 53 | 40° C. | 1.3 times | 1.5 times | 0.20 | 0.6 | 50° C. | 12 times | B |
| Comparative | 101 | 28 | 40° C. | 1.3 times | 1.5 times | 0.20 | 1.2 | 50° C. | 6.5 times | A |
| Example | | | | | | | | | | |
| Comparative | 102 | 23 | 40° C. | 1.3 times | 1.5 times | 0.30 | 1.2 | 50° C. | 6.5 times | A |
| Example | | | | | | | | | | |
| Comparative | 103 | 28 | 40° C. | 1.3 times | 1.5 times | 0.50 | 1.2 | 50° C. | 6.5 times | A |
| Example | | | | | | | | | | |
| Comparative | 104 | 28 | 30° C. | 2.0 times | 3.0 times | 0.20 | 5.0 | 60° C. | 6.5 times | C |
| Example | | | | | | | | | | |
| Comparative | 105 | 43 | 40° C. | 1.3 times | 1.5 times | 0.30 | 1.2 | 50° C. | 14 times | C |
| Example | | | | | | | | | | |

### Comparative Example 106

The backlight side polarizing plate was peeled off from an iPad Air manufactured by Apple, Inc. and the pressure sensitive adhesive layer and the luminance improving film of the peeled polarizing plate were removed to obtain a polarizing plate with a one side protective film.

The obtained polarizing plate was immersed in chloroform to dissolve the protective film, thereby obtaining a polarizer having a thickness of 5 μm.

### Evaluation

The thickness, iodine content, degree of orientation of PVA, absorbance at a wavelength of 250 to 400 nm (hereinafter, abbreviated as “absorbance” in the paragraph), product of iodine content and degree of orientation of PVA, and product of absorbance and degree of orientation of PVA of each prepared polarizer were measured. The iodine content, degree of orientation of PVA, and absorbance were respectively measured by the above-described methods. The measurement results are shown in Table 2 below.

In addition, the degree of polarization, unit transmittance, durability, and unevenness (stretching and dyeing unevenness) of each prepared polarizer were evaluated.

The degree of polarization, unit transmittance, and durability were respectively evaluated by the above-described methods, and unevenness was evaluated by the following method. The measurement results are shown in Table 2 below.

In addition, since breakage occurred at 30% or more at the time of preparation (stretching) of the polarizer in Comparative Examples 104 and 105, these polarizers were not evaluated.

<Stretching Unevenness>

Each prepared polarizer was placed under a fluorescent lamp and observed in an oblique direction at 45° and the stretching unevenness of the polarizer surface was visually confirmed and evaluated based on the following criteria. The evaluation was carried out by a method of relative comparison of simultaneously arranging at least two polarizers among each of the prepared polarizers.

(Evaluation Criteria)
A: Unevenness was not visible.
B: Fine streaks were observed.
C: Streaks were observed and did not withstand practical use.

<Dyeing Unevenness>

Each prepared polarizer was placed under a fluorescent lamp and transmitted light was observed. The dyeing unevenness of the polarizer was visually confirmed and evaluated based on the following criteria. The evaluation was carried out by a method of relative comparison of simultaneously arranging at least two polarizers among each of the prepared polarizers.

(Evaluation Criteria)
A: Unevenness is not visible.
B: Slight shade in the color of the polarizer can be confirmed.
C: Unevenness is clearly visible.

TABLE 2

| | | Polarizer | | | | | |
|---|---|---|---|---|---|---|---|
| | | | | | | Product of | |
| | | | | | | iodine content | Product of |
| | | | | Degree of | | and degree of | absorbance and |
| | | | Iodine | orientation of | | orientation of | degree of |
| | | Thickness | content | PVA | Absorbance* | PVA | orientation of PVA |
| | | [μm] | [g/m²] | [—] | [a.u.] | [g/m²] | [a.u.] |
| Example | 101 | 15 | 0.78 | 0.128 | 26.0 | 0.100 | 3.33 |
| Example | 102 | 12 | 0.71 | 0.130 | 25.2 | 0.092 | 3.28 |
| Example | 103 | 10 | 0.66 | 0.133 | 23.0 | 0.088 | 3.06 |
| Example | 104 | 7 | 0.63 | 0.136 | 18.9 | 0.086 | 2.57 |
| Example | 105 | 5 | 0.60 | 0.141 | 15.0 | 0.085 | 2.12 |
| Example | 106 | 15 | 0.63 | 0.132 | 14.0 | 0.083 | 1.85 |
| Example | 107 | 15 | 0.63 | 0.128 | 17.2 | 0.080 | 2.19 |
| Example | 108 | 15 | 0.62 | 0.130 | 16.2 | 0.081 | 2.11 |
| Example | 109 | 15 | 0.53 | 0.153 | 15.2 | 0.081 | 2.33 |
| Example | 110 | 15 | 0.59 | 0.138 | 12.5 | 0.081 | 1.73 |
| Example | 111 | 15 | 0.53 | 0.154 | 11.0 | 0.082 | 1.69 |
| Comparative | 101 | 15 | 0.63 | 0.110 | 13.5 | 0.069 | 1.49 |
| Example | | | | | | | |
| Comparative | 102 | 10 | 0.50 | 0.114 | 13.0 | 0.057 | 1.48 |
| Example | | | | | | | |
| Comparative | 103 | 15 | 0.75 | 0.100 | 23.5 | 0.075 | 2.35 |
| Example | | | | | | | |
| Comparative | 106 | 5 | 0.41 | 0.100 | 7.6 | 0.041 | 0.76 |
| Example | | | | | | | |

| | | | | Durability | | | |
|---|---|---|---|---|---|---|---|
| | | | | 60° C. | 80° C. | | |
| | | | | Relative | Relative | | |
| | | | | humidity | humidity | | |
| | | Degree of | Unit | 95% | 10% or less | Unevenness | |
| | | polarization | transmittance | 500 hours | 500 hours | Stretching | Dyeing |
| | | [%] | [%] | [%] | [%] | unevenness | unevenness |
| Example | 101 | 99.998 | 43.4 | 0.28 | 0.01 | A | A |
| Example | 102 | 99.997 | 43.4 | 0.32 | 0.02 | A | A |
| Example | 103 | 99.998 | 43.5 | 0.51 | 0.03 | A | A |
| Example | 104 | 99.998 | 43.6 | 0.69 | 0.03 | A | A |
| Example | 105 | 99.997 | 43.6 | 0.82 | 0.04 | A | A |
| Example | 106 | 99.993 | 43.5 | 0.95 | 0.06 | A | A |
| Example | 107 | 99.993 | 42.3 | 1.06 | 0.05 | A | A |
| Example | 108 | 99.985 | 43.5 | 1.05 | 0.07 | A | A |
| Example | 109 | 99.992 | 43.4 | 1.03 | 0.06 | B | A |
| Example | 110 | 99.992 | 43.4 | 1.01 | 0.06 | A | B |
| Example | 111 | 99.992 | 43.4 | 0.98 | 0.06 | B | B |
| Comparative | 101 | 99.993 | 42.3 | 1.21 | 0.06 | C | C |
| Example | | | | | | | |
| Comparative | 102 | 99.994 | 42.4 | 1.68 | 0.08 | C | C |
| Example | | | | | | | |
| Comparative | 103 | 99.996 | 41.3 | 0.35 | 0.01 | C | C |
| Example | | | | | | | |
| Comparative | 106 | 99.993 | 42.2 | 2.06 | 0.10 | C | C |
| Example | | | | | | | |

*Absorbance at a wavelength of 250 to 400 nm

From the results shown in Table 2 above, it was found that the polarizers in which the product of the degree of orientation of PVA and the iodine content was less than 0.08 g/m² exhibited an excellent degree of polarization, but the transmittance or durability was poor, and it was also found that the stretching unevenness and dyeing unevenness were poor (Comparative Examples 101 to 103 and 106).

In contrast, it was found that the polarizers in which the degree of orientation of PVA, the iodine content, and the product of the degree of orientation of PVA and the iodine content were in predetermined ranges maintained an excellent degree of polarization and exhibited a high transmittance and excellent durability, and it was also found that the stretching unevenness and dyeing unevenness were satisfactory (Examples 101 to 111).

Particularly, it was found that the polarizers in which the product of the degree of orientation of PVA and the iodine content was 0.082 g/m² or more and 0.110 g/m² or less exhibited more satisfactory durability (Examples 101 to 106 and 111). Particularly, it was found that among Examples 101 to 106 and 111, the polarizers in which the absorbance at a wavelength of 250 to 400 nm was 15 or more and 30 or less exhibited further more satisfactory durability (Examples 101 to 105).

Further, it was found that in the polarizers in which the product of the degree of orientation of PVA and the absorbance at a wavelength of 250 to 400 nm was 1.70 or more and 4.0 or less, the stretching unevenness and dyeing unevenness were further suppressed (Examples 101 to 110).

What is claimed is:

1. A polarizer comprising:
a polyvinyl alcohol-based resin; and
iodine contained in the polyvinyl alcohol-based resin,
wherein a thickness of the polarizer is 2 to 20 μm,
a degree of orientation of the polyvinyl alcohol-based resin is 0.11 or more and 0.16 or less,
a content of the iodine is more than 0.50 g/m² and 1.0 g/m² or less, and
a product of the degree of orientation of the polyvinyl alcohol-based resin and the iodine content is 0.08 g/m² or more and 0.11 g/m² or less.

7. The polarizer according to claim 1,
wherein the product of the degree of orientation of the polyvinyl alcohol-based resin and the iodine content is 0.082 g/m² or more and 0.110 g/m² or less.

3. The polarizer according to claim 1,
wherein an absorbance of the polarizer at a wavelength of 250 to 400 nm is 15 or more and 30 or less.

4. The polarizer according to claim 2,
wherein an absorbance of the polarizer at a wavelength of 250 to 400 nm is 15 or more and 30 or less.

5. The polarizer according to claim 3,
wherein a product of the degree of orientation of the polyvinyl alcohol-based resin and the absorbance of the polarizer at a wavelength of 250 to 400 nm is 1.70 or more and 4.0 or less.

6. The polarizer according to claim 4,
wherein a product of the degree of orientation of the polyvinyl alcohol-based resin and the absorbance of the polarizer at a wavelength of 250 to 400 nm is 1.70 or more and 4.0 or less.

7. A polarizing plate comprising:
the polarizer according to claim 1.

8. A polarizing plate comprising:
the polarizer according to claim 2.

9. A polarizing plate comprising:
the polarizer according to claim 3.

10. A polarizing plate comprising:
the polarizer according to claim 4.

11. A polarizing plate comprising:
the polarizer according to claim 5.

12. A polarizing plate comprising:
the polarizer according to claim 6.

13. An image display device comprising:
the polarizer according to claim 1.

14. An image display device comprising:
the polarizer according to claim 2.

15. An image display device comprising:
the polarizer according to claim 3.

16. An image display device comprising:
the polarizer according to claim 4.

17. An image display device comprising:
the polarizer according to claim 5.

18. An image display device comprising:
the polarizer according to claim 6.

19. An image display device comprising:
the polarizing plate according to claim 7.

20. An image display device comprising:
the polarizing plate according to claim 8.
